(19) United States
(12) Patent Application Publication
(10) Pub. No.: US 2026/0344044 A1
(43) Pub. Date: Oct. 29, 2026

(54) CARRIER COMPRISING A CHARGE-TRAPPING LAYER, COMPOSITE SUBSTRATE COMPRISING SUCH A CARRIER AND ASSOCIATED PRODUCTION METHODS

(71) Applicant: Soitec, BERNIN (FR)

(72) Inventors: Oleg Kononchuk, BERNIN (FR); Marcel Broekaart, BERNIN (FR); Morgane Logiou, BERNIN (FR)

(21) Appl. No.: 19/159,775

(22) PCT Filed: Nov. 27, 2023
(86) PCT No.: PCT/EP2023/083212

§ 371 Date: Aug. 26, 2025

(30) Foreign Application Priority Data
Nov. 29, 2022 (FR) FR2212458

(51) Int. Cl. H10D 86/00; H10D 86/01

(52) U.S. Cl. CPC H10D 86/201; H10D 86/01

(57) ABSTRACT

A carrier for a composite substrate includes an interlayer arranged on a base substrate. The interlayer comprises a trapping layer in contact with the base substrate, and the trapping layer is formed of a silicon-rich oxide including silicon at an atomic concentration of silicon of between 70% and 90% and oxygen at an atomic concentration of between 10% and 30%. A composite substrate may incorporate such a carrier and a method may be used for producing this composite substrate.

### CROSS-REFERENCE TO RELATED APPLICATIONS

This application is a national phase entry under 35 U.S.C. § 371 of International Patent Application PCT/EP2023/083212, filed Nov. 27, 2023, designating the United States of America and published as International Patent Publication WO 2024/115410 A1 on Jun. 6, 2024, which claims the benefit under Article 8 of the Patent Cooperation Treaty of French Patent Application Serial No. FR2212458, filed Nov. 29, 2022.

### TECHNICAL FIELD

The present disclosure relates to a support having an electrical charge-trapping layer, the support being intended to receive a crystalline thin film by a layer transfer technique. A composite substrate formed of such a support finds its application in the field of integrated electronic components, in particular, radiofrequency (RF) components that process signals whose frequency can typically be between 20 kHz and 300 GHz, or more. The thin film of the composite substrate may consist of a semi-conductor material such as silicon or an insulating material, such as a material having piezoelectric and/or ferroelectric properties. In addition to the support as such, the disclosure also relates to the composite substrate comprising this support and to which the thin film has been transferred. The disclosure also relates to the method for manufacturing the support and the method for manufacturing the composite substrate incorporating such a support.

### BACKGROUND

There is a rich prior art in this field.

Thus, and by way of example of a first approach, U.S. Pat. Nos. 7,585,748 and 9,293,473 propose forming the electrical charge-trapping layer (and more concise designated “trapping layer” in the rest of this description) in the form of a layer of polycrystalline silicon arranged on a base substrate made of silicon.

The boundaries of the silicon grains constituting the polycrystalline layer constitute traps for the electrical charges that may be circulating. These traps can be formed by the incomplete or dangling chemical bonds at these boundaries. This prevents conduction in the trapping layer, which consequently has high resistivity, typically greater than 1000 Ohms·cm.

In addition to the polycrystalline silicon, the trapping layer can be formed more generally from a non-single-crystalline layer having structural defects, such as dislocations, grain boundaries, amorphous zones, interstices, inclusions, pores, etc., these structural defects being able to trap electrical charges.

The trapping layer may thus be formed by the implantation of a relatively heavy species, such as argon, in a surface thickness of the base substrate, in order to form therein the structural defects constituting the electrical traps. As an example of this approach, U.S. Pat. No. 10,224,233 proposes a trapping layer formed of nanocavities arranged in a surface zone of a base substrate, these nanocavities being obtained by implantation of helium and nitrogen.

This layer can also be formed by porosification of a surface thickness of the base substrate. U.S. Pat. No. 10,290,533 thus proposes a trapping layer consisting of pores formed at the surface of the base substrate, oxidized and filled with a semiconductor, polycrystalline or amorphous material.

For reasons of implementation simplicity, the trapping layer is however generally formed by depositing a layer of polycrystalline silicon deposited on the base substrate. In order to preserve the polycrystalline quality of this layer during heat treatments that can be applied to the support, an amorphous layer, consisting of silicon dioxide, for example, can advantageously be provided on the base substrate before the deposition of the charge-trapping layer, as proposed by U.S. Pat. Nos. 8,765,571 and 9,129,800.

U.S. Patent Application Publication No. 2015/115480 proposes to form the trapping layer as a stack of amorphous or polycrystalline elementary polycrystalline layers. These elementary layers may, in particular, be composed of silicon, germanium, silicon germanium. This multilayer is sought to make the trapping layer more robust to heat treatments than the support is caused to undergo, in particular, during the manufacturing steps of the composite substrate employing such a support.

U.S. Pat. No. 11,251,265 proposes in certain embodiments to form the trapping layer from a polycrystalline main layer and, inserted in this layer, an intermediate layer formed from an alloy of silicon and carbon.

In International Patent Application Publication No. WO2021110513 a polycrystalline layer of silicon carbide is formed directly on the base substrate, before placing the polycrystalline trapping layer therein.

In European Patent Document EP3195352, the trapping layer is selected from the group consisting of carbon nitride, silicon carbon nitride and a combination of these materials.

In European Patent Document EP3195353, the amorphous or crystalline trapping layer is formed of a material having a wide band gap and, in particular, a material selected from the group consisting of aluminum nitride, boron nitride, indium nitride, gallium nitride, aluminum gallium nitride, aluminum-gallium-indium nitride, aluminum-gallium-indium and boron nitride.

In European Patent Document EP3189544, the trapping layer is an amorphous layer of carbon-doped silicon. This layer is formed on a silicon base substrate having a surface layer of silicon oxide.

In European Patent Document EP3266038, the deposition of the layer of polycrystalline silicon is preceded by the formation of a nucleation layer consisting of a silicon oxide, a silicon nitride or a silicon oxynitride. This nucleation layer is heat-treated to form holes therein.

U.S. Pat. No. 10,468,295 discloses forming a silicon nitride or silicon oxynitride layer between a polycrystalline silicon trapping layer and a silicon oxide dielectric layer. This layer can be obtained by deposition or nitriding/oxynitriding of the trapping layer and aims to preserve the resistivity of the trapping layer and to avoid its recrystallization.

In general, this prior art reveals the need to have a support for a composite substrate comprising a trapping layer that has a high resistivity and stable temperature. This temperature stability is an important characteristic, since the manufacture of a composite substrate comprising such a support implements heat treatments typically increasing the temperature of the support at more than 1000 °C, which tends to cause the desired characteristics of the support to be lost by recrystallization of the layer and separation of the structural defects of this layer.

U.S. Patent Application Publication No. 2015/0287783 recognizes in its introduction that high-temperature annealings (1000 °C to 1100 °C according to this document) lead to reducing the number of traps in a trapping layer, which affects its performance. To overcome this problem, this document proposes to produce this trapping layer after the manufacture of the devices and by avoiding exposing the structure thus formed to an excessive temperature (exceeding 200 °C to 400 °C according to this document).

The need for temperature stability is not limited to the robustness of the trapping layer during the manufacture of the composite substrate. It also relates to operating stability, temperature, and the integrated electronic components ultimately formed on the composite substrate. These components tend to show decreasing RF performance with the increase in temperature, in particular, when the latter exceeds 100 °C.

It will be recalled that the RF performance of a component can be estimated by performing an RF characterization of the composite substrate (and more particularly of the support of this composite substrate) n or wherein the component is intended to be formed. As documented in the publication “White paper—RF SOI Characterization” dated January 2015 and published by SOITEC, the RF performance of a substrate can be characterized by a second harmonic distortion measurement HD2.

It is, therefore, generally sought to form a support comprising a trapping layer making it possible to form a support having high RF performance and stable with the temperature, these performances being established by the measurement HD2.

Of course, the manufacture of this layer is also as simple and inexpensive to manufacture as possible, which promotes the search for solutions leading to as small a layer thickness as possible and a surface as smooth as possible in order to avoid preparing this surface, for example, by polishing, as much as possible.

In order to limit the thickness of the trapping layer without damaging the performance of this layer, and therefore improving the production rate, it is necessary for the latter to have a high density of electrical traps. A high trap density also makes it possible to make the RF performance of the substrate less sensitive to the diffusion of species into the trapping layer, which tends to electrically passivate the traps. It may, for example, be the diffusion of hydrogen or lithium (in particular, when the thin film of the composite substrate is formed of a lithium-based piezoelectric material).

### BRIEF SUMMARY

It is an object of the disclosure to address these problems at least in part. More specifically, one object of the disclosure is to propose a support for a composite substrate, the support comprising a trapping layer having a large density of traps for electrical charges. One object of the disclosure is to propose a support comprising a trapping layer, this layer being able to have a thickness less than a trapping layer of the prior art, while providing a support with similar RF performance. Another object of the disclosure is to propose a support comprising a trapping layer whose RF performance is more stable in temperature than a support of the prior art. Yet another object of the disclosure is to propose a support, comprising a trapping layer, which is simpler to manufacture than a support of the prior art.

With a view to achieving this goal, the object of the present disclosure proposes a support for a composite substrate, the support comprising an interlayer arranged on a base substrate, the interlayer comprising a trapping layer in contact with the base substrate formed of a silicon-rich oxide consisting of silicon in an atomic concentration of silicon of between 70% and 90% and of oxygen in an atomic concentration of between 10% and 30%.

According to other advantageous non-limiting features of the disclosure, taken alone or according to any technically feasible combination:
the trapping layer is formed of an amorphous matrix wherein crystalline silicon inclusions reside;
the interlayer is entirely comprised of the trapping layer;
the interlayer also comprises a dielectric layer disposed on and in contact with the trapping layer;
the trapping layer has a thickness of between 10 nm and 30 micrometers, preferably between 50 nm and 500 nm.

According to another aspect, the object of the disclosure proposes a composite substrate comprising a single-crystal thin film arranged on a support as proposed previously. The single-crystal thin film may consist of silicon or a piezoelectric material

According to yet another aspect, the object of the disclosure proposes a method for manufacturing a substrate comprising:
providing a support as proposed above;
a step of transferring a single-crystal thin film onto the support to form the composite substrate.

According to the disclosure, the transfer step comprises the application of an annealing having a thermal budget greater than or equal to 850 °C for two hours.

### BRIEF DESCRIPTION OF THE DRAWINGS

Other features and advantages of the disclosure will emerge from the following detailed description of embodiments of the disclosure with reference to the accompanying figures, in which:

FIG. 1 shows a support according to the disclosure;

FIG. 2 shows a composite substrate employing a support according to the disclosure;

FIGS. 3A-3C show a trapping layer according to the disclosure in various crystalline shapes;

FIGS. 4A and 4B show graphs of the atomic concentration profile of silicon in an interlayer of a support according to the disclosure;

FIG. 5 shows the nature and size of the crystalline silicon inclusions that can be present in a trapping layer according to the disclosure;

FIG. 6 shows an SRP type measurement carried out on a support according to the disclosure;

FIG. 7 compares the evolution of the RF performance of a support, measured in HD2, with the temperature for a support according to the disclosure and a support of the prior art.

### DETAILED DESCRIPTION

### Description of the Support

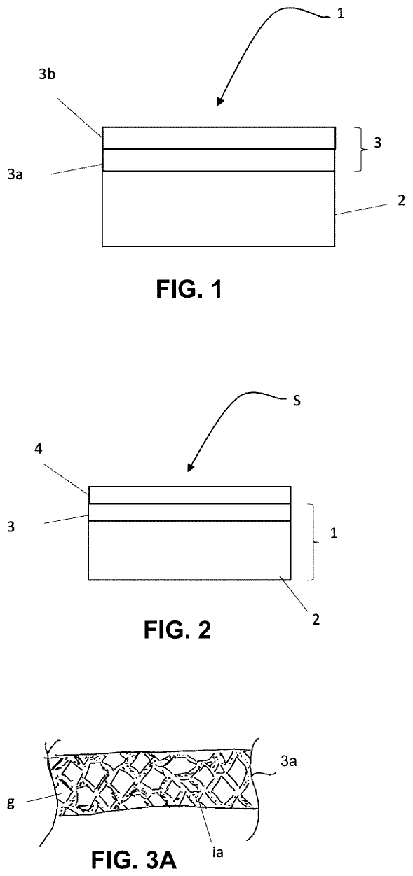

FIG. 1 shows a support intended to receive, by a layer transfer technique, a crystalline thin film to form a composite substrate S, shown in FIG. 2. In a very general manner, the support 1 comprises an interlayer 3 arranged on a base substrate 2. The interlayer 3 comprises a trapping layer 3a in contact with the base substrate 2. The interlayer may also comprise, as shown in FIG. 1, a dielectric layer 3b arranged on and in contact with the trapping layer 3a, but this dielectric layer 3b is optional. It is noted that it is not imperative that the interlayer 3 has, in such a case, an abrupt interface between the trapping layer 3a and the dielectric layer 3b. This interlayer 3 may thus have, in its thickness, a progressive transition of its composition resulting in defining the trapping layer 3a and the dielectric layer 3b. This aspect of the disclosure will be shown in a subsequent section of the present disclosure.

When the dielectric layer 3b is not present, the intermediate layer 3 consists entirely of the trapping layer 3a.

Conventionally, the support 1 can be in the form of a circular wafer, the diameter of which can be 100, 150, 200, 300 or even 450 mm.

The base substrate 2 of the support 1 on which the interlayer 3 rests typically has a thickness of several hundred micrometers. Preferably, the base substrate 2 has a high resistivity, greater than 1000 ohm centimeters, and even more preferably, greater than 2000 ohm centimeters. The density of the charges, holes or electrons, which are likely to move in the base substrate 2, is thus limited. However, the disclosure is not limited to a base substrate 2 having such a resistivity, and it also provides RF performance advantages when the base substrate 2 has a more compliant resistivity, of the order of a few hundred ohm centimeters, for example, less than 1000 ohm·cm, or less than 500 ohm·cm or even less than 10 ohm·cm.

For availability and cost reasons, the base substrate 2 preferably consists of monocrystalline silicon. It may, for example, be a CZ silicon substrate with a low interstitial oxygen content of between 6 and 10 ppm, or an FZ silicon substrate that particularly has a naturally very low interstitial oxygen content. It can also be a CZ silicon substrate having a high quantity of interstitial oxygen (designated by the expression “High Oi”) of more than 26 ppm, which will be heat-treated to ultimately provide the desired properties. The base substrate 2 may alternatively be formed from another material: it may, for example, be sapphire, glass, quartz, silicon carbide, etc.

In certain circumstances and, in particular, when the trapping layer 3a is thick enough, for example, more than 10 micrometers thick, the base substrate 2a may have standard resistivity, of less than 1 kohm·cm.

In order to seek to preserve the properties of the trapping layer 3a during the heat treatments that the support 1 can undergo, an amorphous layer, made of silicon dioxide, for example, directly inserted between the base substrate 2 and the trapping layer 3a, can optionally be provided. When the base substrate 2 is made of silicon, this amorphous layer can be a native oxide layer present on the surface of this substrate or intentionally formed by chemical or thermal oxidation of the base substrate. But the trapping layer 3a, according to the description, which is particularly stable with the temperature, and the presence of the amorphous layer is optional.

According to an important aspect of the present description, the trapping layer 3a is a silicon-rich oxide layer. This silicon-rich oxide layer consists of silicon, oxygen, and optionally nitrogen.

The term “silicon-rich” means that the atomic concentration of silicon in the layer is between 40% or 50% and 99.9%. The oxygen and, optionally, the nitrogen are present in substoichiometric atomic concentrations.

It will be noted that a trapping layer of the prior art, made of polycrystalline silicon, has an atomic oxygen concentration of less than 0.01% (and therefore has an atomic silicon concentration of greater than 99.99%). The trapping layer formed of a silicon-rich oxide proposed by the present description therefore has an atomic oxygen concentration at least ten times greater than a conventional trapping layer, which distinguishes it from such a layer and gives it quite specific properties.

Such a layer, in particular, has the advantage of having a particularly high defect density, forming traps for the electrical charges. It is therefore capable of exhibiting a very high resistivity, up to approximately 10\hat{ }12 ohm·cm. More generally, this resistivity is between 10\hat{ }5 ohm·cm and 10\hat{ }12 ohms·cm. By comparison, a dielectric layer of silicon (stoichiometric) oxide has a resistivity of the order of 10\hat{ }15 ohm·cm and a trapping layer of the prior art, of polycrystalline silicon, has a typical resistivity of the order of 10\hat{ }4 ohm·cm.

It is possible to determine the composition of the trapping layer by secondary ion mass spectrometry (so-called “SIMS” measurements). For reasons of precision, it will however be preferred to use a technique of depth profiling by X-ray electron spectroscopy (XPS) with ion beam etching, called “X-ray Photoelectron Spectroscopy depth profiling” in the art. These techniques make it possible to determine the atomic concentration of silicon, oxygen and nitrogen of the trapping layer 3a.

It is not required for the atomic concentrations of silicon, oxygen and, optionally, nitrogen to be constant in the thickness of the trapping layer 3a. In certain embodiments, this concentration can vary, while remaining within the concentration limits giving this layer the quality of being rich in silicon. In some other embodiments, these atomic concentrations are chosen to be constant.

Advantageously, and to confer its resistive character, the silicon-rich trapping layer is not intentionally doped. It does not comprise any other species than silicon, oxygen and, optionally, nitrogen. If other species are incorporated into the layer, they are in proportions not exceeding simple traces, less than 0.1%.

The crystalline quality of a silicon-rich layer depends very strongly on its atomic oxygen concentration and, optionally, in nitrogen. It also depends on the heat treatments that this layer has received.

Generally, a silicon-rich layer is formed from an amorphous matrix. This amorphous matrix may comprise crystalline inclusions of silicon or crystalline silicon grains, the density and size of these inclusions and/or of these grains in the amorphous matrix being dependent on the relative proportions of oxygen, nitrogen and silicon in the layer and heat treatments that it has received. In extreme cases, a silicon-rich layer may be entirely amorphous or entirely polycrystalline, the amorphous matrix then being in the latter case reduced to amorphous inclusions present between the grains of the poly-crystal.

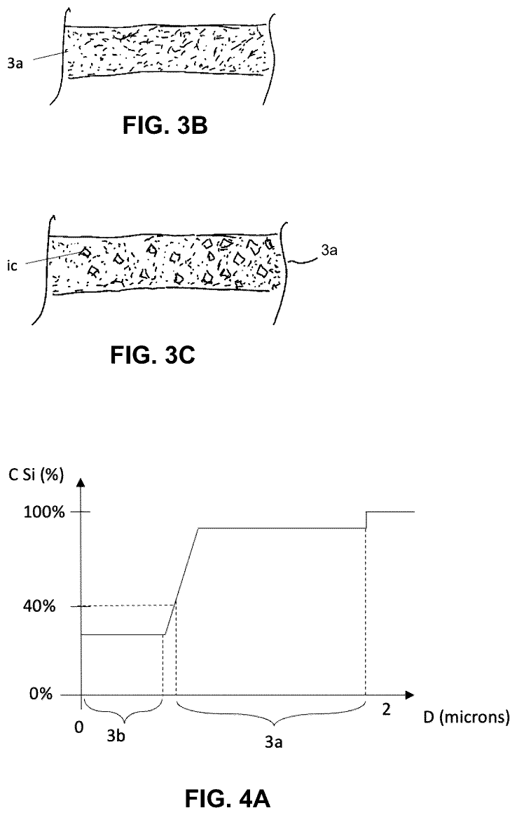

Thus, when the atomic concentrations of oxygen and nitrogen are low, and the atomic concentration of silicon is therefore significant, for example, greater than or equal to 99%, a silicon-rich layer takes a polycrystalline form, shown in FIG. 3A. The grains g, or some of them, can be coated with an amorphous material thickness, this amorphous material then being located at the grain boundaries of the polycrystalline layer. The amorphous material may also be in the form of inclusions ia between the grains of the polycrystalline layer. These inclusions ia may have, according to the atomic concentration of oxygen and, optionally, nitrogen, of the layer, a dimension typically within the range extending from 10 nm to 100 nm. This amorphous material, rich in oxygen and/or in nitrogen, consists of aggregates of the species composing the layer, such as aggregates of SiO, SiN, SiON and oxygen and/or nitrogen precipitates.

The polycrystalline layer is formed of grains g of silicon, the size distribution of which has a peak (which defines the average size of the grains) close to 100 nm or less than 100 nm. This average size is much lower than the average size of the grains of a conventional trapping layer, made of polycrystalline silicon (on the order of 300 nm).

When the atomic concentration of silicon in a silicon-rich layer is lower, for example, in the range extending from 40% to 90% or extending from 50% to 90%, and comprises an oxygen concentration and, optionally nitrogen, greater than or equal to 10%, the latter takes a mainly amorphous form. It is then composed of elements of nanometric dimensions of Si, SiO, SiON, SiN, which gives it this amorphous nature, as shown in FIG. 3B.

Between the polycrystalline state and the fully amorphous state, the crystalline quality of the layer can be of an intermediate nature. Thus, and as shown in FIG. 3C, a silicon-rich layer may take the form of an amorphous matrix, wherein crystalline silicon inclusions ic are embedded. These inclusions ic may have a size of less than 10 nm, and sometimes even less than 5 nm.

By increasing the atomic concentration of silicon in the trapping layer 3a, these inclusions ic tend to grow to form grains g and close to the polycrystalline structure presented above with reference to FIG. 3A.

It is noted that the amorphous, polycrystalline or intermediate form can be affected by the heat treatments applied to this layer during or after its manufacture, or even during the use of the support. Also, the oxygen, nitrogen and/or silicon concentration limits are given by way of illustration only. The person skilled in the art will be able to adjust these concentrations, using a series of experiments that is very simple to carry out, making it possible to arrive at a trapping layer 3a having the desired structural characteristics. The exact crystalline nature of the layer can, in particular, be observed by microscopy, for example, by transmission electron microscopy (TEM) or by Raman measurement.

The experiments carried out by the applicant have shown that certain compositions of the trapping layer 3a consisting of silicon-rich oxide were particularly stable in temperature and dense in traps for electrical charges. Such layers are therefore capable of having particularly interesting radiofrequency performance.

Thus, in certain preferred embodiments, the trapping layer 3a can consist of:
silicon in an atomic concentration of between 60% and 90%, advantageously between 70% and 90% and
oxygen in an atomic concentration of between 10% and 40%, advantageously between 10% and 30%.

In other preferred embodiments, the trapping layer 3a can consist of:
silicon in an atomic concentration of between 30% and 77%, and
oxygen in an atomic concentration of between 8% and 40%,
nitrogen in an atomic concentration of between 8% and 45%.

“Stable in temperature” means that after exposure to a minimum thermal budget of 850 °C for 2 hours, a support 1 according to the disclosure has a resistivity characteristic measured by the HD2 technique (presented in introduction) less than −80 dB. Some products have greater requirements. Thus, it is expected that a support 1 of a composite substrate of silicon on insulation (formed from a layer of single-crystalline silicon transferred onto the support) has a resistivity characteristic HD2 less than −80 dB after exposure to a thermal budget of 1100 °C for 2 hours. It is expected that a support 1 of a piezoelectric composite substrate on insulation (formed from a layer of piezoelectric single-crystalline transferred onto the support) has a resistivity characteristic HD2 less than −80 dB after exposure to a thermal budget of 900 °C for 2 hours.

In these preferred embodiments, the trapping layer 3a takes the form of an amorphous matrix, wherein crystalline silicon inclusions ic are embedded. These inclusions ic have a size of less than 10 nm, and sometimes even less than 5 nm.

In general, the trapping layer 3a has a thickness that may be between 10 nm and 30 microns, and typically between 20 nm and 5 microns. Preferably, this thickness is greater than 50 nm or at 100 nm so that the quantity of traps is sufficient. Preferably, this thickness is less than 2 micrometers, or even less than 1 micrometer, to limit the amount of material, and any stresses that this layer may apply to the support 1, which could deform it. However, this advantageous range of thickness is in no way limiting, and it is possible to choose to form a trapping layer 3a of any thickness that is suitable, according to the needs of the intended application.

In particular, the measurements carried out by the applicant (and which will be the subject of a final section of this description) have shown that a thickness of between 30 nm and 200 nm could contain a sufficient quantity of traps.

The trapping layer 3a has a first surface in contact with the base substrate 2. It has a second surface opposite the first surface. In certain embodiments, in particular, when the trapping layer 3a is relatively thin, for example, less than 500 nm or less than 100 nm, or even less than 50 nm, or when the atomic oxygen concentration is relatively low, less than 10%, or according to the deposition technique implemented, the second surface of the trapping layer 3 has a low roughness so that it is not necessary to process it in order to improve its surface condition. This roughness may be less than 0.6 nm in mean square value measured over a field of 10 micrometers by 10 micrometers.

As mentioned in an earlier paragraph of this description, the interlayer 3 may comprise, in addition to the trapping layer 3a that has just been described, a dielectric layer 3b, arranged on and in contact with the trapping layer. “Dielectric layer” refers to a layer having a resistivity on the order of 10 ohm·cm and greater. The resistivity of the dielectric layer 3b is, in any case, greater than the resistivity of the trapping layer 3a.

This dielectric layer 3b can, generally, be of any nature and of a thickness that is suitable. But advantageously, a support 1 in accordance with the present description has a dielectric layer 3b composed of silicon, oxygen and/or nitrogen, that is the same elements as those that may compose the trapping layer 3a. This feature makes it possible to form the interlayer 3 in a single step, by successively forming the trapping layer 3a and the dielectric layer 3b, “in situ,” for example, in the same deposition equipment.

In general, “in situ” refers to the fact that the support 1 is held in a controlled atmosphere during the manufacture of the interlayer, for example, by keeping it in a single chamber of the deposition equipment, or by passing it between multiple chambers of this equipment while maintaining it in a confined and controlled environment. This avoids contamination by pollutants from the atmosphere (boron or phosphorus, for example), which would be likely to degrade the RF performance of this support.

The dielectric layer 3b is distinguished from the trapping layer 3a in that its atomic silicon concentration is less than 40%. Its atomic concentration of oxygen and, optionally, in nitrogen, can be in at least one stoichiometric proportion.

The dielectric layer 3b has a thickness typically between 10 nm and 10 microns, essentially dictated by the need to apply the composite substrate S that the support 1 is intended to form.

In the integrated approach of “in situ” formation of the interlayer 3, the exposed face of this layer can benefit from the low roughness presented previously for the trapping layer 3a. This interlayer 3 can thus have a free surface of less than 0.6 nm in mean square value measured over a field of 10 micrometers per 10 micrometers.

Advantageously, the dielectric layer 3b consists at least in part of silicon oxide or silicon nitride, in particular, in a surface part. A support 1 having an exposed surface whose nature, oxide or silicon nitride, is perfectly known, is then provided. This surface may, in particular, be prepared by polishing, cleaning, activation, according to controlled methods, to transfer a thin film by a layer transfer technology, and thus form a composite substrate.

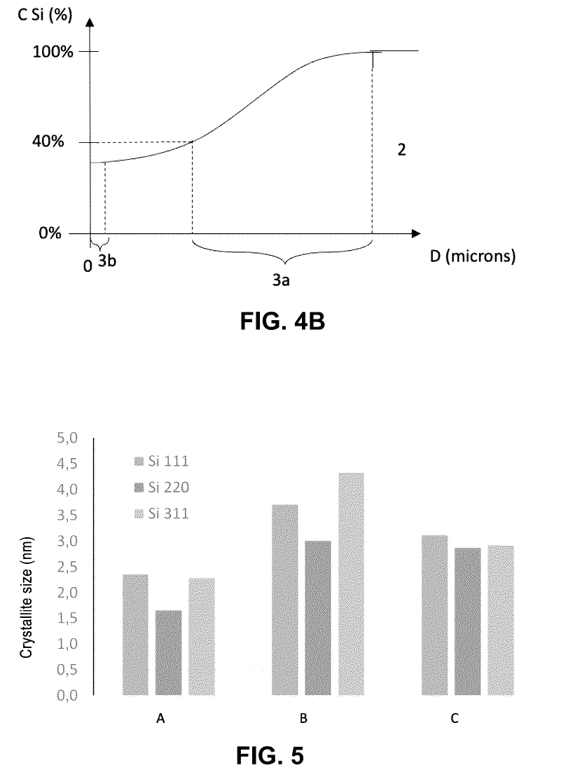

When the dielectric layer 3b is entirely made of silicon oxide or silicon nitride, in an atomic concentration of stoichiometric silicon, this atomic concentration can vary abruptly at the interface between the trapping layer 3a and the dielectric layer 3b, that is the transition zone is less than 50 nm. Such a configuration is shown in the graph of FIG. 4A. In this graph, shows the evolution of the atomic concentration of silicon CSi (in %), in the thickness D of the interlayer 3a, from the free surface (corresponding to a zero depth on the x-axis D) toward the surface resting the base substrate 2 is shown. The abrupt transition between the dielectric layer 3b and the trapping layer 3a is observed.

However, provision may also be made for the atomic concentration of oxygen and, optionally, the atomic concentration of nitrogen to vary continuously in the thickness of the interlayer 3. The transition zone is then greater than 50 nm. The atomic concentration of silicon can, in particular, continuously decrease in the thickness of the interlayer 3 moving away from the base substrate in order, for example, to form a superficial part of the interlayer layer 3 made of silicon oxide or of silicon nitride. Such a configuration is shown in the graph of FIG. 4B. The atomic concentration of nitrogen, if it is not zero in the trapping layer 3a, can evolve continuously or abrupt so that the atomic concentration of nitrogen is zero in the superficial part, when the latter consists of silicon oxide.

### Description of the Composite Substrate

As already mentioned, the purpose of the support substrate 1 is to receive, by transfer, a thin film 4 and thus form a composite substrate S, shown by way of illustration in FIG. 2. The thin film is generally of crystalline nature, and advantageously single-crystalline. The support substrate 1 has suitable properties (in terms of surface roughness and deformation in particular) or has been previously treated to receive such a thin film 4.

As is well known per se, this transfer is usually carried out by assembling a free face of a donor substrate to the support substrate 1, preferably by molecular adhesion. This assembly is generally facilitated by the presence of an amorphous layer, for example, made of silicon dioxide or silicon nitride on at least one of the faces to be assembled. When the interlayer 3 of the support superficially has such an amorphous surface layer (which may be the trapping layer 3a or the dielectric layer 3b), it is not necessary for the donor substrate to itself be provided with one. However, this is not excluded, and it is sometimes possible for the donor substrate to be provided with a thin amorphous thickness (for example, a layer of silicon dioxide having a thickness of less than 150 nm).

The nature of the donor substrate is chosen according to the desired nature of the thin film 4. It may, therefore, be a substrate formed from a single-crystal semiconductor, for example silicon, or a substrate formed from a single-crystal piezoelectric material or comprising a superficial layer of such a single-crystal piezoelectric material. It may in this case be lithium tantalate or lithium niobate.

It is also possible that the donor substrate has finished or semi-finished components, the transfer aiming to place these components on the support 1 to take advantage of its radio frequency properties. However, in the case of preferred use, the donor substrate lacks any components in order to transfer a thin film 4 consisting of a material of crystalline nature, and advantageously single-crystal.

Like the support 1, the donor substrate may take the form of a circular plate, the dimension of which may correspond to that of the support.

After this assembly step, which may include a consolidation annealing at a moderate temperature (less than 600 °C), the donor substrate is reduced in thickness to form the thin film 4. This reduction step can be carried out by mechanical or chemical thinning. The reduction in thickness of the donor substrate can preferably be carried out by fracturing in an embrittlement plane previously introduced into the donor substrate, for example, by implanting light species such as hydrogen and/or helium. This embrittlement plane defines, with the free surface of the donor substrate, the thin film 4.

After this step of thinning or, preferably, of fracturing, steps of finishing the thin film 4 can be applied, such as a polishing step, a heat treatment in a reducing or neutral atmosphere, a sacrificial oxidation, etc. The finishing steps comprise the exposure of the composite substrate to relatively high temperatures, greater than 600 °C, for a duration of at least one hour. For example, when the added thin film 4 is made of silicon, the composite structure S is exposed to a thermal budget of at least 1000 °C for 1 hour. When the added thin film 4 consists of a piezoelectric material, the composite structure S is exposed to a thermal budget of at least 600 °C for 1 hour.

In all cases, the trapping layer 3a being stable in temperature, the RF property of the composite substrate S is not excessively altered by the heat treatments applied to it during the finishing steps.

At the end of these steps, a composite substrate S formed from the single-crystal thin film transferred onto the support 1 is available.

In a particularly interesting example of application, the thin film 4 is a single-crystal piezoelectric thin film attached directly to the trapping layer 3a. In other words, the support does not have a dielectric layer 3a. The single-crystal piezoelectric thin film may be lithium tantalate or lithium niobate. Such a composite substrate is particularly suitable for receiving surface wave acoustic devices. The trapping layer 3a, due to its nature, has acoustic characteristics similar to a layer of silicon dioxide usually employed in these devices. In such a case, the trapping layer then has the double function of improving the radiofrequency characteristics of the component and of propagating the acoustic waves appropriately.

In another example of an interesting application, the interlayer 3 has a dielectric layer 3b made of silicon dioxide, the thickness of which can be between 10 nm and 10 microns. The thin film 4 is a layer of single-crystal silicon. The composite substrate S then forms a silicon-on-insulation substrate.

### Method for Manufacturing the Support

The manufacture of the support 1, which has been the subject of a preceding section of the present description, is particularly simple and achievable with standard industrial deposition equipment.

According to one example, the base substrate 2 is provided in a chamber of conventional deposition equipment. As is well known per se, the base substrate 2 can be prepared before deposition to remove a layer of native oxide from its surface. This step is not mandatory and this oxide can be preserved. It is even possible to intentionally form a relatively thin amorphous layer on the surface of the base substrate 2, for example, a layer of silicon oxide when this substrate 2 is made of silicon, by chemical or thermal treatment, as was mentioned previously.

Regardless of the treatments applied to this base substrate 2 before or just after its introduction into the chamber of the deposition device, this chamber is then passed through by flows of precursor gases, which react to progressively form the interlayer 3 on the base substrate 2. A sequence of formation of the interlayer 3, therefore, comprises a step of depositing, directly on the base substrate 2 provided or not with its amorphous layer, a silicon-rich oxide trapping layer 3a, according to one of the preferred embodiments presented above.

As an example, the step of depositing the trapping layer 3a can be carried out by chemical vapor deposition, for example, according to a PECVD (Plasma-Enhanced Chemical Vapor Deposition) technique or according to a LPCVD (Low-Pressure Chemical Vapor Deposition) technique.

The deposition step comprises the introduction, into the deposition chamber, of a first silicon precursor gas (for example, silane, of formula SiH4) and at least one second oxygen precursor gas (nitrous oxide or dioxygen), and optionally nitrogen (for example, nitrous oxide of formula N2O). These precursor gases can be supplemented by a carrier gas, for example, nitrogen, argon, or helium. It is naturally possible to provide distinct precursor gases for oxygen and nitrogen. As is well known per se, the precursor gases react in the deposition chamber, under controlled pressure and temperature conditions, to progressively form the trapping layer 3a.

When the deposition is carried out via the PECVD technique, it is carried out at a moderate temperature, typically between 150 °C and 600 °C, and at atmospheric pressure, for example, of a few Torr (i.e., a few hundred pascals). When carried out via the LPCVD technique, the deposition is carried out at a temperature typically between 550 °C and 750 °C, and at atmospheric pressure, for example, of a few Torr (i.e., a few hundred pascals).

Of course, the disclosure is in no way limited to a particular technique of deposition or of particular precursor gases. As alternatives to the techniques already described, it is possible to envisage forming the interlayer 3, by an APCVD (Atmospheric Pressure Chemical Vapor Deposition) technique in a temperature range typically between 1000 °C and 1150 °C. It may also be a HDP CVD (High-Density Plasma Chemical Vapor Deposition) technique, typically carried out at a relatively low temperature, between 100 °C and 450 °C, and at a pressure of the order of 10 mTorr (i.e., of the order of 1.33 Pascal). It is also possible to envisage a SACVD (“Sub-Atmospheric Chemical Vapor Deposition”) technique. It is also possible to use an epitaxy built to form this layer by a generic technique of vapor phase deposition.

As for the precursors, and independently of the deposition technique envisaged, besides the silane and the nitrous oxide already described, it may be provided to use dichlorosilane or trichlorosilane as a silicon precursor gas. It is possible to use dioxygen as an oxygen precursor gas. It is not necessary to provide a nitrogen precursor gas. The carrier gas, generally a neutral gas, may consist of or comprise nitrogen, hydrogen, argon.

Regardless of the chosen deposition technique, the atomic concentration of silicon, oxygen and nitrogen is chosen by controlling the flows of the precursor gases and, in particular, the ratio of the flow of the first silicon precursor gas to the flow of the second oxygen precursor gas and optionally nitrogen. The higher this ratio is, the lower the atomic concentration of oxygen, and optionally of nitrogen. This flow ratio can be kept constant to form a silicon-rich oxide layer having an atomic concentration of oxygen and, optionally, constant nitrogen, but it is also possible to vary this ratio. This variation can be continuous or abrupt, according to whether or not marked interfaces are desired in the interlayer 3 as shown in FIGS. 4A and 4B.

The flows are kept for long enough to form a desired thickness of the trapping layer 3a, between a few minutes and several hours.

The deposition step can be followed, in the deposition chamber directly, or in another equipment, by a step of annealing the trapping layer 3a. This annealing can be carried out with annealing at a temperature between 750 °C and 1100 °C. The annealing can affect the crystallographic nature of the trapping layer as obtained directly after the deposition step.

For example, the annealing can make it possible to reveal inclusions ic of crystalline silicon of nanometric size in a totally amorphous trapping layer 3a in its state as deposited. It may modify the size or the density, when these inclusions ic are present in the trapping layer 3a as deposited.

At the end of this first deposition step, the trapping layer 3a is therefore arranged on the base substrate 2. The deposition can be controlled, in its thickness or in its components, so that the layer has a particularly low roughness, less than 0.6 nm in mean square value measured over a field of 10 micrometers by 10 micrometers.

In some variants, the sequence of formation of the interlayer 3 comprises, after the step of depositing the trapping layer 3a, a step of depositing the dielectric layer 3b. This second step can be carried out in equipment separate from that which implemented the step of depositing the trapping layer 3a, and according to a deposition technique that can be different from the one implemented during the first step. As already stated, this makes it possible to envisage forming a dielectric layer 3b of any suitable nature.

However, advantageously, the step of depositing the dielectric layer 3b is carried out “in situ.” It is also possible to use the same precursor gases, for example, in a single chamber, a dielectric layer 3b made of silicon oxide or silicon nitride.

In this approach, the flows of precursor gases are controlled during the sequence of formation of the interlayer 3, and more precisely the ratio of these flows, in order to suddenly or gradually form the trapping layer 3a and then, secondly, the dielectric layer 3b. The circulation of the flow of the precursor gases can be interrupted in order to apply the heat treatment step (or a plurality of heat treatment steps) during the formation of the interlayer 3. This heat treatment can also be carried out at the end of the formation of the interlayer 3, “in situ” in the chamber of the deposition equipment or “ex situ” in equipment separate from the deposition equipment.

In other words, the sequence of forming the interlayer 3 is controlled to continuously or abruptly vary the atomic concentration of silicon. For example, the atomic concentration of silicon can be chosen to continuously decrease in the thickness of the interlayer 3 when moving away from the base substrate 2. In this case, it is possible to form an interlayer 3 having a trapping layer 3a in contact with the base substrate 2 (and having atomic concentrations of oxygen and “sub-stoichiometric” nitrogen), the atomic concentration of one of these species increasing to form a dielectric layer 3b, for example, made of silicon dioxide or silicon nitride comprising an atomic concentration of stoichiometric silicon, on the trapping layer 3a.

It is also possible to choose to form the interlayer 3 by using multiple deposition techniques. Thus, the trapping layer 3a can be formed in a first chamber of a deposition equipment and according to a first technique (by PECVD, for example). The dielectric layer 3b can be formed in a second chamber and according to a second technique, different from the first (for example, HDP). This approach makes it possible to benefit from the advantages of each of these techniques. HDP technology, in particular, makes it possible to form layers of low roughness.

In this case, it is possible, and advantageously, to perform these “in-situ” steps, within the same equipment, by controlling the transit between the two chambers and without exposing the support, during this transit, to the ambient atmosphere.

The dielectric layer 3b advantageously comprises a surface thickness of silicon dioxide or silicon nitride.

### Example 1: Silicon-Rich Trapping Layer Consisting of Silicon, Oxygen and Nitrogen

By way of illustration, a plurality of supports according to the preceding section of the present description were produced for the purpose of characterizing them.

The base substrates of the supports all had a high resistivity (of 3 kohm·cm). The trapping layers were formed by a PECVD technique. PECVD equipment was introduced into the deposition chamber wherein the base substrate had previously been placed, a first silicon precursor gas consisting of silane (SiH4) and a second oxygen and nitrogen precursor gas consisting of nitrous oxide (N2O). These precursor gases were supplemented with a nitrogen-bearing gas. The deposition chamber was kept at a pressure of 3 Torr (i.e., 400 Pascal), and the plasma (at 13.55 MHz) had a power of 300 W.

The ratio between the stream of nitrous oxide and the flow of silane (N2O/SiH4, the flows being measured in standard cubic centimeters per minute) was controlled at a ratio of between 0.05 and 0.5, to develop respectively:
supports (of type 1) having trapping layers composed of 76.5% silicon, 8.5% oxygen and 15% nitrogen.
supports (of type 2) having trapping layers composed of 60.6% silicon, 19.2% oxygen and 20.2% nitrogen.
Supports (of type 3) having trapping layers composed of silicon in an atomic concentration of between 30% and 60%, oxygen in an atomic concentration of between 10% and 40%, and nitrogen in an atomic concentration of between 10% and 45%.

These atomic concentrations were measured by XPS measurement with ion beam etching.

The flows were maintained to form a trapping layer with a thickness chosen from 200 nm or 1 micrometer for the supports of type 1 and 2, and between 70 nm and 500 nm for the supports of type 3.

In some cases, a 200 nm silicon oxide dielectric layer was formed on the trapping layer, in situ, by controlling the nitrous oxide and silane streams in a N2O/SiH4 ratio of 5.

At the end of these deposition steps, the support formed from the base substrate, of the trapping layer and, in some cases, of a dielectric layer was annealed at 900 °C or at 1100 °C for 2 hours in a neutral atmosphere for supports of type 1 and 2, 850 °C for 2 hours for supports of type 3.

The plurality of supports thus manufactured consists of a matrix of supports having a wide variety of configurations, which has been subjected to numerous characterization measurements.

Observations by TEM microscopy were thus carried out on supports of type 1 and 2 comprising trapping layers of 200 nm and not having a dielectric layer and, in particular, for a trapping layer of a support of type 1 comprising 8.5% oxygen and for a trapping layer of a support of type 2 comprising 19.2% oxygen, each annealed at 1100 °C. These characterization measurements have made it possible to observe that in both cases, the trapping layers were formed of an amorphous matrix wherein crystalline inclusions were present whose size was less than 10 nm, similarly to the illustration of FIG. 3C.

Observations by TEM microscopy carried out on supports of type 3, annealing at 850 °C only revealed that the trapping layers were formed from an amorphous matrix, with a rare presence of crystalline inclusions. Likewise, similar measurements made on a 200 nm type 2 trapping layer (comprising 19.2% oxygen) but annealed at 900 °C only showed that this layer was entirely amorphous and, therefore, had no detectable crystalline inclusion.

The assumption is that these crystalline inclusions, for the ranges of atomic compositions of the trapping layers studied, develop around a temperature of 900 °C (according on the atomic concentration of silicon) to be fully visible by TEM after having undergone an annealing of 1100 °C.

XRD characterization made it possible to identify that these crystalline inclusions were formed from silicon crystallites, the orientation of which could be 110, 220 or 311. FIG. 5 shows the distribution of these crystallites and their dimensions for three trapping layers of different natures:
Layer “A”: support of type 1 (8.5% oxygen) annealed at 900 °C
Layer “B”: support of type 1 (8.5% oxygen) annealed at 1100 °C
Layer “C”: support of type 2 (19.2% oxygen) annealed at 1100 °C

Series of measurements aimed at electrically characterizing the trapping layer and the support has also been produced.

The measurements of the SRP for “Spreading Resistance Profiling” are carried out first. To carry out this measurement, the support is prepared by polishing to form a chamfer making the various layers that make up the support accessible, in their depth. The ends of two electrodes spaced apart by a fixed distance and forming a segment parallel to the edge of the chamfer are then applied to the chamfered part of the substrate. A determined voltage is applied between the two electrodes, the resistance is measured between them, then from this measurement the electrical resistivity of the support at the measurement depth is deducted. By carrying out this measurement at different distances relative to the edge of the chamfer (corresponding to different depths in the substrate), it is then possible to plot a curve of resistivity profile, which shows the resistivity as a function of the depth in the substrate. More detailed description of this characterization is found in the document “White paper—RF SOI Characterisation” presented in the introduction of this application.

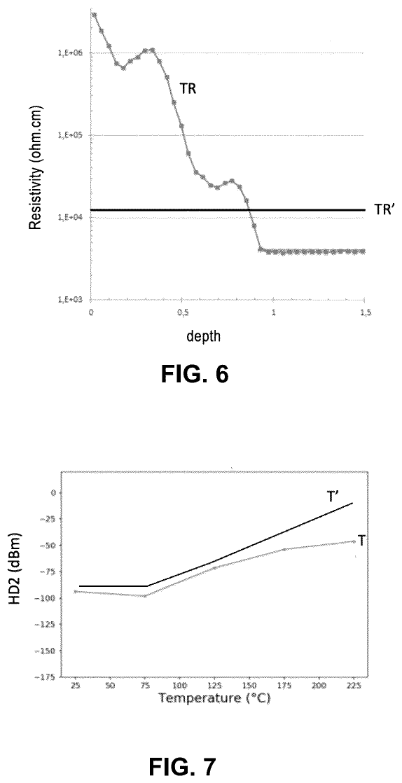

In the graph of FIG. 6, the x-axis shows the depth of the measurement (in micrometers) in one of the supports of the matrix. This distance is taken from the exposed surface of the support; here, the exposed surface of the trapping layer. The y-axis shows the resistivity (in ohm·cm) as measured by the measurement SRP.

The support subjected to the SRP measurement consisted of a high-resistivity base substrate (3.5 kohm·cm), and a trapping layer obtained by a PECVD technique by controlling the nitrous oxide/silane ratio to 0.15. The trapping layer was composed of 76.5% silicon, 8.5% oxygen and 15% nitrogen. The trapping layer has a thickness of 1 micrometer. The resistivity measurement is reported by the line TR in this FIG. 6. As a comparison, the line TR′ is plotted, which corresponds to the maximum resistivity of a conventional trapping layer consisting of a thickness of 2 micrometers of polycrystalline silicon. In FIG. 6, the much higher resistivity of the trapping layer formed from a silicon-rich oxide that has resistivity measurements can be seen, which may exceed 10\hat{ }6 ohm·cm, whereas such a measurement is generally of the order of 10\hat{ }4 for a conventional trapping layer.

The characterization SRP measures the electrical performance of the trapping layer as such, but does not make it possible to entirely anticipate the RF performance of the support. This performance is indeed also affected by other parameters than the one related to the resistance characteristic of the trapping layer, for example, its thickness or the resistivity characteristics of the base substrate. The measurement HD2, presented in the introduction of this application, makes it possible to evaluate the RF performance of a support more generally when it is used as a support for a composite substrate receiving RF components.

HD2 measurements (15 dBm input signal, at 900 MHz) were therefore carried out on supports resulting from the test matrix of types 1, 2 and 3, in particular, on the supports of this matrix having a dielectric surface layer of 200 nm. The value HQF (theoretical value of HD2 for a “perfect” trapping layer) is expected to −95 dB. The results of these measurements are reproduced below.
five supports of type 1 comprising a trapping layer of 200 nm and annealed at 1100 °C for 2 hours: −91 dBm on average for these five supports;
eight supports of type 2 comprising a trapping layer of 200 nm and annealed at 900 °C for 2 hours: −90 dBm on average for these eight supports;
More than eight type 3 supports and annealed at 850 °C for 2 hours: −82 dBm on average;
A support comprising a 1.7-micrometer polycrystalline silicon trapping layer (prior art): −67 dBm.

These measurements, compared to those obtained on a support having a conventional trapping layer, clearly show the benefit of a support according to the disclosure, even when the trapping layer is relatively thin, 200 nm, much thinner than the trapping layer of 1.7 micrometers taken in comparison.

FIG. 7 compares the evolution of the RF performance, measured in HD2, of a support with the temperature. FIG. 7, in particular, compares this evolution for a support of the prior art (denoted T′ in the figure) having a trapping layer of polycrystalline silicon of 1.7 microns with a support having a trapping layer of a support of type 1 (denoted T in the figure) that is 1 micrometer thick. The base substrates of the two supports were the same. It is interesting to note that the performance HD2 of a support according to the disclosure is much less affected by the temperature than a support in accordance with the prior art.

In another series of experiments aiming to determine the robustness of the trapping layers to lithium contamination, supports of type 3 have been used to produce composite substrates comprising a thin film 4 made of a single-crystal piezoelectric material (made of lithium tantalate) in accordance with the layer transfer method described above. A dielectric layer of silicon oxide (denoted “BOX” in the table below) is arranged between the trapping layer (denoted “TR” in this table) and the thin piezoelectric layer. During the steps of preparing the supports and manufacturing of the composite substrate, the trapping layer was exposed to a maximum temperature of 850 °C for 2 hours.

The following table summarizes the characteristics of the composite substrates that have been the subject of these experiments, and have both their RF performance (in HD2 measurement) and the concentration of lithium in the trapping layer:

| | | | | | | | | |
|---|---|---|---|---|---|---|---|---|
| BOX Thickness | 500 | nm | 500 | nm | 500 | nm | 100 | nm |
| TR Thickness | 70 | nm | 100 | nm | 170 | nm | 170 | nm |
| Measurement HD2 | −81 | dB | −81 | dB | −81 | dB | −80 | dB |

| | | | | |
|---|---|---|---|---|
| Lithium Dose | 2.5 E12 | n/a | 7.0 E11 | 1.5 E12 |
| (at/cm\hat{ }2) | | | | |

In comparison, a composite substrate comprising a piezoelectric thin film transferred onto a support comprising a conventional layer of polycrystalline silicon trapping and provided with a dielectric layer of 250 nm has a measure of RF performance greater than −70 dB for a lithium dose of 1 E12 at/cm\hat{ }2.

It is, therefore, noted that the trapping layer of a support of type 3 can incorporate a large amount of lithium, which tends to passivate its traps, but without losing its RF property (measured by HD2). It is concluded that the trapping layers of a support of type 3 comprise a very large trap density and is able to incorporate a large quantity of passivating species, without this affecting its performance.

At the end of these experiments, it is noted that a charge-trapping layer consisting of silicon, oxygen and nitrogen, in the following proportions:
silicon in an atomic concentration of between 30% and 60%, and
oxygen in an atomic concentration of between 8% and 40%,
nitrogen in an atomic concentration of between 8% and 45%
are able to enter into the composition of a support whose RF performance is stable in temperature, exhibiting satisfactory performance (less than or equal to −80 dB in HD2 measurement) even after having undergone a relatively high temperature annealing.

This performance is achieved even for relatively thin thicknesses, from 75 nm.

These supports are also robust to contamination of an electrical passivating element. They therefore do not require placing a thick barrier dielectric layer between a thin film capable of providing its passivating elements and the support. A silicon oxide dielectric layer of 100 nm is, for example, sufficient in the example of a composite substrate comprising a thin film comprising lithium.

Finally, it is noted that these properties are obtained for a wide range of composition of silicon, oxygen and nitrogen, which facilitates the production of this trapping layer, since it is not necessary to control with very high precision its exact composition during its manufacture.

### Example 2: Trapping Layer Rich in Silicon and Consisting of Silicon and Oxygen

In another series of experiments, attempts have been made to evaluate the possibility of using a silicon-rich trapping layer consisting of silicon and oxygen (and therefore without nitrogen).

Supports (of type 4) having trapping layers having:
an atomic concentration of oxygen, respectively equal to 10%, 40%, 55% and 60%, and silicon, respectively equal to 90%, 60%, 45% and 40%.
thicknesses between 200 nm and 1 micron;
annealing for two hours at 900 °C or 1100 °C.

The (average) RF performance measurements measured by the HD2 technique (15 dBm input signal, at 900 MHz), as a function of the silicon concentration are as follows:

| % Si | 90% | 60% | 45% | 40% |
|---|---|---|---|---|
| HD2 | <−80 dB | <−85 dB | >−40 dBM | >−40 dBM |

The measurement HQF (theoretical value of HD2 for a “perfect” trapping layer) is expected to be −88 dB.

In these measurements, the supports of type 4 had the same level of RF performance measured by HD2 whatever the thickness of the trapping layer. This thickness therefore does not seem to affect this performance.

However, the table shows that this performance is dictated by the composition of the trapping layer.

TEM observations carried out on these samples have shown that satisfactory RF performance was linked to the presence of crystallites, distributed homogeneously in the layer. Their size could be of the order of 5 nm just after the deposition of the trapping layer, but could grow under the effect of the annealing is greater than 10 nm after the latter (in particular, after an annealing of 1100 °C for 2 hours).

At the end of the experiments that were conducted, there is a silicon-rich trapping layer, stable in temperature, consisting of:
silicon in an atomic concentration of between 60% and 90%, and
oxygen in an atomic concentration of between 10% and 40%.

Advantageously, it consists of silicon in an atomic concentration of between 70% and 90% and oxygen in an atomic concentration of between 10% and 30%.

The characterization measurements that have just been presented, therefore, clearly show the benefit of a trapping layer and a support according to the disclosure. It is noted that RF performance (in HD2 measurement) can easily be improved relative to what has been exposed, by preparing a trapping layer thicker than the 1 maximum micrometer of the layers of the supports of the test matrix. It is possible to envisage, as seen above, that this thickness can be between 10 nm and 30 microns.

Of course, the invention is not limited to the embodiment described and variant embodiments can be added thereto without departing from the scope of the invention as defined by the claims.

1. A support for a composite substrate, comprising:
a base substrate; and
an interlayer on the base substrate, the interlayer comprising a trapping layer in contact with the base substrate, the trapping layer comprising a silicon-rich oxide including silicon at an atomic concentration between 70% and 90% and oxygen at an atomic concentration between 10% and 30%.

2. The support of claim 1, wherein the trapping layer comprises an amorphous matrix wherein crystalline silicon inclusions reside.

3. The support of claim 2, wherein the interlayer consists essentially of the trapping layer.

4. The support of claim 2, wherein the interlayer further comprises a dielectric layer on and in contact with the trapping layer.

5. The support of claim 1, wherein the trapping layer has a thickness between 10 nm and 30 microns.

6. A composite substrate, comprising:
a support, including:
a base substrate; and
an interlayer on the base substrate, the interlayer comprising a trapping layer in contact with the base substrate, the trapping layer comprising a silicon-rich oxide including silicon at an atomic concentration between 70% and 90% and oxygen at an atomic concentration between 10% and 30%; and
a single-crystal thin film on the interlayer.

7. The composite substrate of claim 6, wherein the single-crystal thin film comprises silicon or a piezoelectric material.

8. A method for manufacturing a composite substrate, comprising:
providing a support including:
a base substrate; and
an interlayer on the base substrate, the interlayer comprising a trapping layer in contact with the base substrate, the trapping layer comprising a silicon-rich oxide including silicon at an atomic concentration between 70% and 90% and oxygen at an atomic concentration between 10% and 30%; and
transferring a single-crystal thin film onto the support to form the composite the transferring comprising applying an annealing having a thermal budget greater than or equal to 850 °C for two hours.

9. The support of claim 1, wherein the interlayer consists essentially of the trapping layer.

10. The support of claim 9, wherein the trapping layer has a thickness between 10 nm and 30 micron.

11. The support of claim 10, wherein the trapping layer has a thickness between 50 nm and 500 nm.

12. The support of claim 1, wherein the interlayer further comprises a dielectric layer on and in contact with the trapping layer.

13. The support of claim 12, wherein the trapping layer has a thickness between 10 nm and 30 micron.

14. The support of claim 13, wherein the trapping layer has a thickness between 50 nm and 500 nm.

15. The support of claim 5, wherein the trapping layer has a thickness between 50 nm and 500 nm.
